(19) United States
(12) Patent Application Publication
(10) Pub. No.: US 2013/0163200 A1
(43) Pub. Date: Jun. 27, 2013

(54) Display Device

(71) Applicant: SANYO Electric Co., Ltd., Osaka (JP)

(72) Inventor: Shohei TAKAHASHI, Osaka (JP)

(73) Assignee: SANYO ELECTRIC CO., LTD., Osaka (JP)

(21) Appl. No.: 13/649,062

(22) Filed: Oct. 10, 2012

(30) Foreign Application Priority Data
Dec. 27, 2011 (JP) 2011-285590
Dec. 27, 2011 (JP) 2011-285591

(51) Int. Cl. H05K 5/02

(52) U.S. Cl. CPC H05K 5/0213
USPC 361/692; 361/695

(57) ABSTRACT

A display device has a display panel, a cabinet configured to accommodate the display panel, a ventilating portion configured to communicate with the space inside the cabinet, a lid configured to covers the ventilating portion, a first and second vents formed on the lid, a first hood provided on the first vent, the first hood has an opening facing the second vent, and a second hood provided on the second vent, the second hood has an opening facing the first vent.

### CROSS-REFERENCE TO RELATED APPLICATIONS

This application claims the benefit of priority of Japanese Patent Application No. 2011-285590, and 2011-285591, all of which are filed on Dec. 27, 2011, and all of which are incorporated by reference herein in their entirely.

### TECHNICAL FIELD

The instant application relates to a water-proofing structure of an electronic device for outdoor use such as display device.

### BACKGROUND

In a display device which is arranged outdoors, the temperature of a LCD (Liquid Crystal Display) panel may rise because of the rise of an environment temperature or direct sunlight. This may cause malfunction in the display apparatus. One idea is to give an air flow between the LCD panel and a front glass using a fan so as to cool the LCD panel. This idea is disclosed in Japanese Published Application JP2011-128432A1 which was filed by the applicant.

Originally, the above mentioned display device was employed inside the other apparatus such as a vending machine. Thus, it was not necessary to provide a waterproofing structure for the display device because usually the vending machine already has the waterproofing structure. However, the applicants decide to sell these display devices alone, in other words, the display devices which are not employed inside the vending machine. In such case, it is necessary to provide a waterproofing structure inside the display device.

### SUMMARY

The display device of the instant disclosure has a display panel, a cabinet configured to accommodate the display panel, a ventilating portion configured to communicate with the space inside the cabinet, a lid configured to covers the ventilating portion, a first and second vents formed on the lid, a first hood provided on the first vent, the first hood has an opening facing the second vent, and a second hood provided on the second vent, the second hood has an opening facing the first vent.

### BRIEF DESCRIPTION OF THE DRAWINGS

FIG. 1 is a front perspective view of the display device 1.

FIG. 2 is a rear perspective view of the display device 1.

FIG. 3 is an exploded perspective view of the display device 1 when viewed from the rear side.

FIG. 4 is a sectional view fractured at the plane containing an A-A line shown in FIG. 2.

FIG. 5 is a rear perspective view of the display device 1, where the air intake side lid unit 60 and the air exhaust side lid unit 80 are opened.

FIG. 6 is a front view of the air intake side lid unit 60.

FIG. 7 is a side view of the air intake side lid unit 60.

FIG. 8 is a bottom view of the air intake side lid unit 60.

FIG. 9 is a rear view of the air intake side lid unit 60.

FIG. 10 is a sectional view fractured at the plane containing a B-B line shown in FIG. 6.

FIG. 11 is an exploded perspective view of the air intake side dustproof filter 35.

FIG. 12 is a rear view of the display device 1, when the display device 1 is utilized in vertical installation mode.

FIG. 13 is a side view of the display device 1 when fractured at the plane containing the B-B line shown in FIG. 2, and when the front cover 22 is opened.

FIG. 14 is an enlarged view of FIG. 13.

FIG. 15 is a side view of the display device 1 when fractured at the plane containing the B-B line shown in FIG. 2, and when the front cover 22 is closed.

FIG. 16 is an enlarged view of FIG. 15.

FIG. 17 is an exploded perspective view of the display device 1 when viewed from the front side.

FIG. 18 is an enlarged view of FIG. 17.

### DETAILED DESCRIPTION

In the following detailed description, numerous specific details are set forth by way of examples in order to provide a thorough understanding of the relevant teachings. However, it should be apparent to those skilled in the art that the present teachings may be practiced without exemplary details. In other instances, well known methods, procedures, components, and/or circuitry have been described at a relatively high-level, without detail, in order to avoid unnecessarily obscuring aspects of the present concepts. In exchange for the present disclosure herein, the Applicants desire all patent rights described in the claims. Therefore, the patent rights are not intended to be limited or restricted by the following detailed description and accompanying figures.

The display device of an instance example may be installed outdoors in order to display still images, video images or information. For example, the display device is installed outdoors to show a pedestrian a still or moving image for advertisements. This display device may be attached to a pillar provided on a ground or an outer wall of a building. This display device may be arranged inside the other apparatus such as a vending machine and installed outdoors.

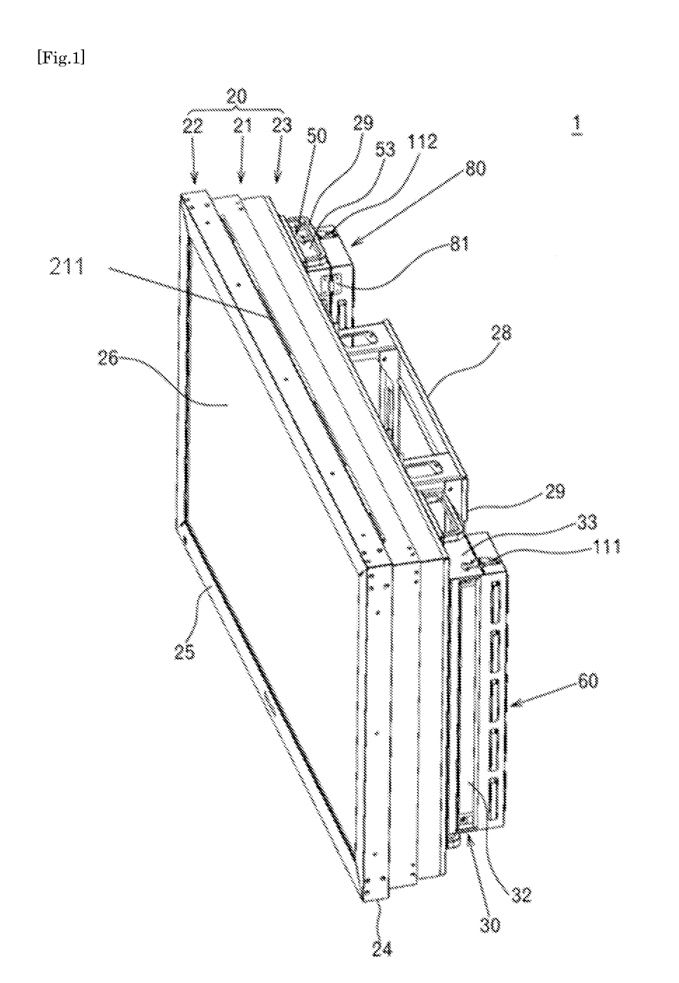

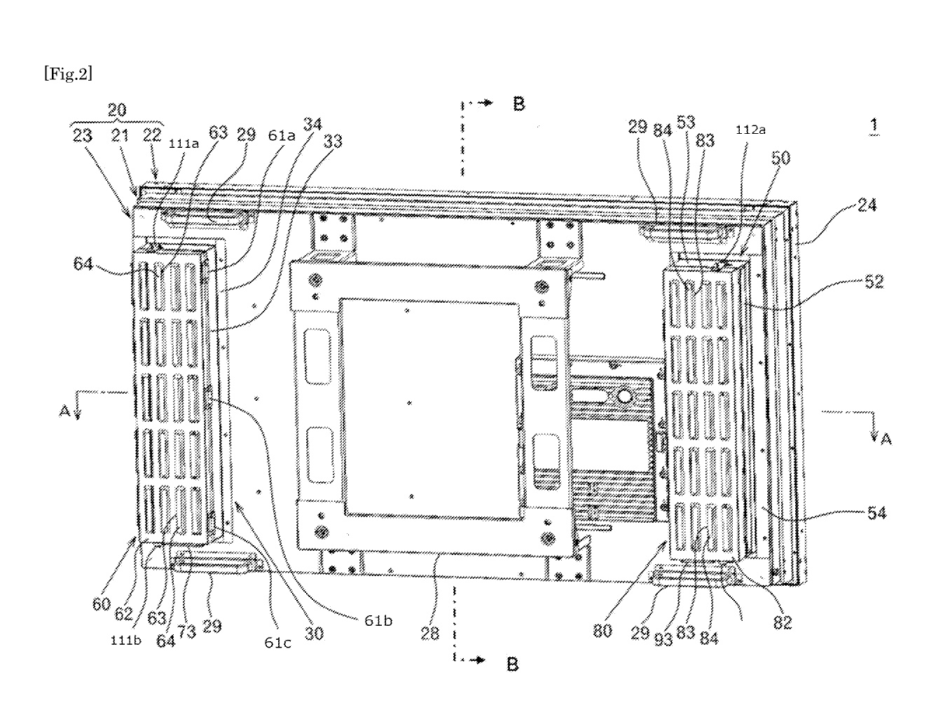

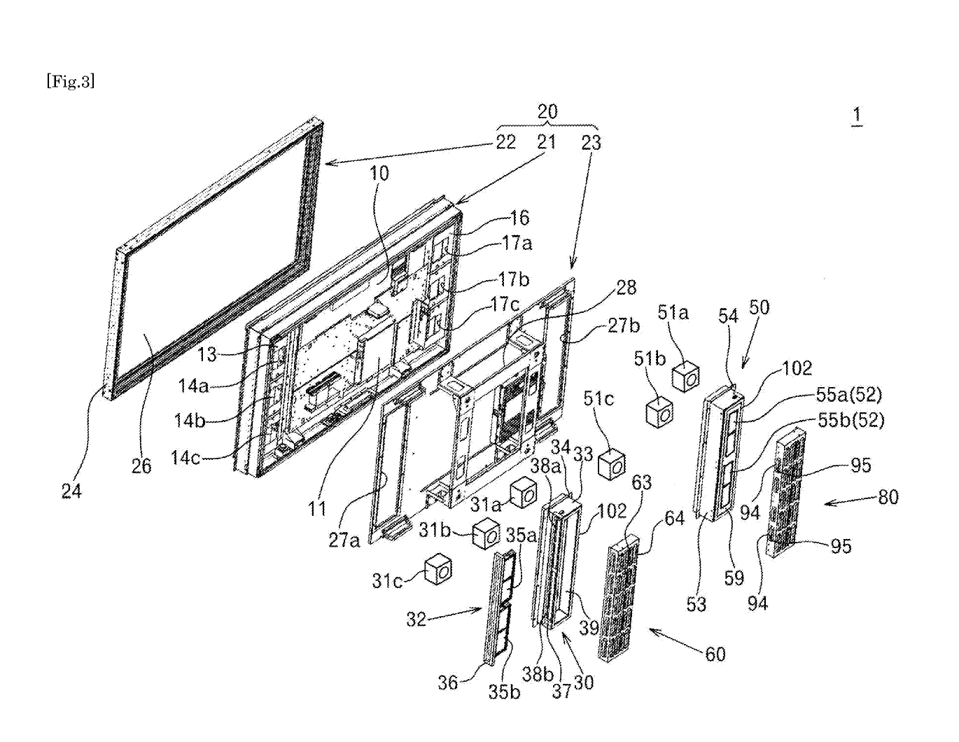

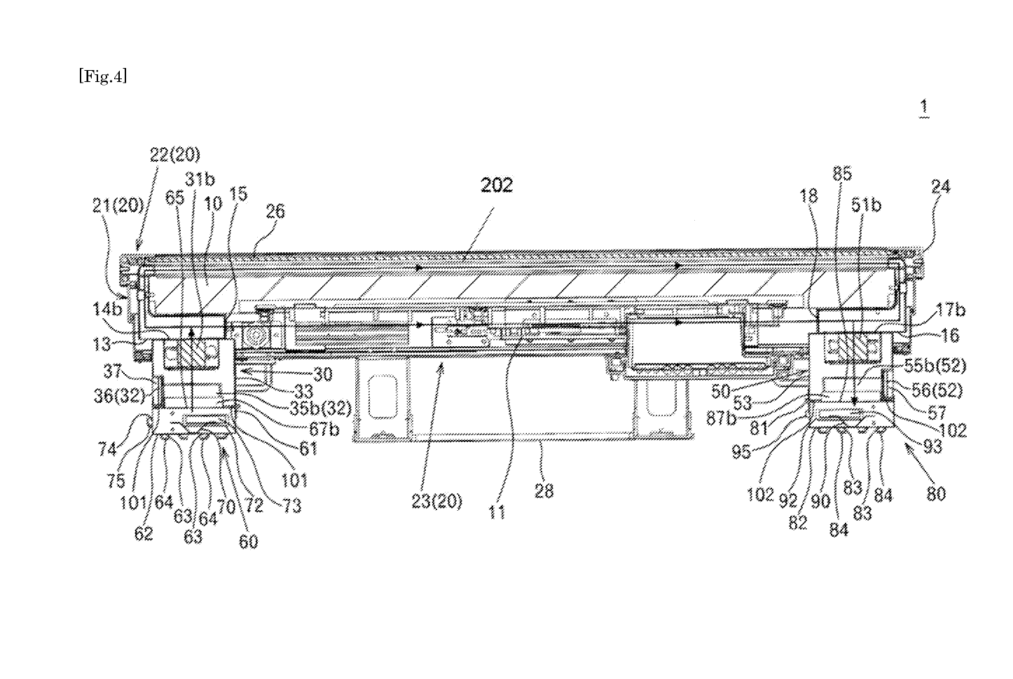

FIG. 1 is a front perspective view of the display device 1. FIG. 2 is its rear perspective view. FIG. 3 is its exploded perspective view when viewed from the rear side. FIG. 4 is a sectional view fractured at the plane containing an A-A line shown in FIG. 2.

The display device 1 has a LCD panel 10 (see FIG. 3 or 4) which displays an image, and a cabinet 20 which accommodates this LCD panel 10 inside. The LCD panel 10 has a polarizing filter, a color filter, a liquid crystal layer, transistor arrays, a light-guide, and a light source. Instead of the LCD panel 10, the other types of panel such as a plasma display panel, or an organic EL panel, may be utilized.

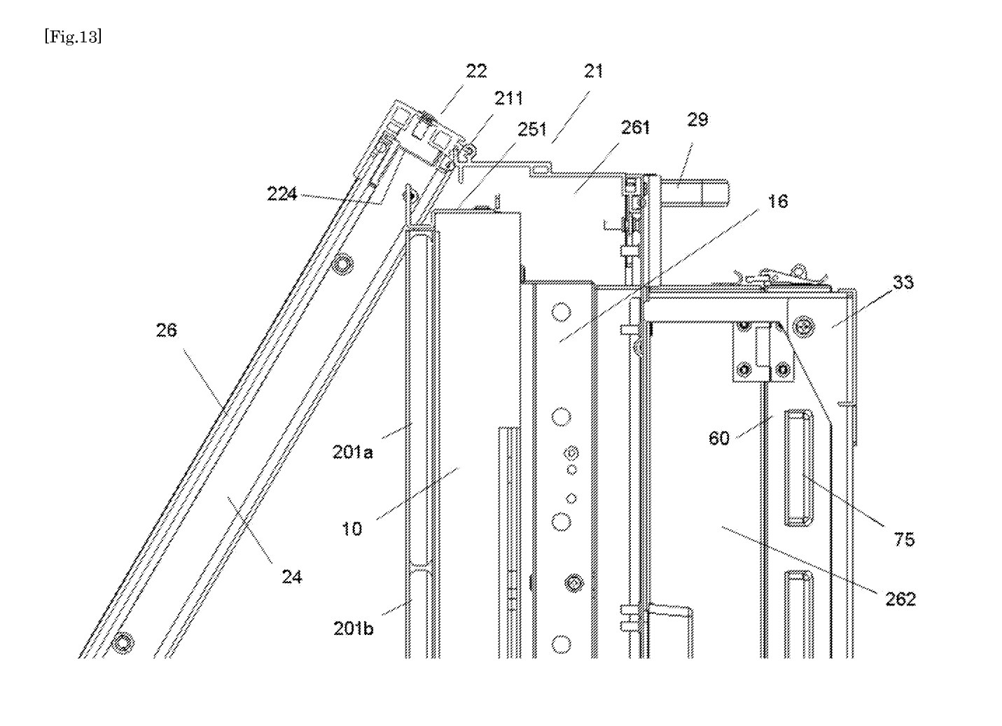

The cabinet 20 has a first frame 21 having four sides to which the LCD panel 10 is attached inside, a front cover 22 which is attached to the first frame 21 and covers the front side of the LCD panel 10, and a back cover 23 which is attached to the first frame 21 and covers the rear side of the LCD panel 10. The front cover 22 has a second frame 24 having four sides that is fixed screwed to the first frame 21. In the front edge side of the second frame 24, a flange 25 is formed toward the center side of the display screen. In the back side of the flange 25, a front glass 26 is attached so as to cover the opening of the second frame 24. The front glass 26 is provided in order to protect the LCD panel 10. The front cover 22 is fixed rotatable to the first frame 21. That is, the front cover 22 is rotatable around a receiving portion 211 (see FIG. 1). The receiving portion 211 is semicircular groove shaped object and is provided near the upper edge of the first frame 21. Thereby, it is able to open the front cover 22, and is able to clean (or sweep) the front side of the LCD panel 10. The detailed structure is mentioned later referring to FIGS. 13 to 18. In the rear side of the front glass 26, (i.e. the side facing the LCD panel 10) a touch panel sheet may be attached. Thereby, a user of the display device 1 can operate from the front side of the LCD panel 10. since the touch panel sheet is attached in the rear side of the front glass 26, the touch panel sheet does not get wet even if the display device 1 is installed outdoors.

The back cover 23 is a rectangular board material. Near the short hand sides of the back cover 23, rectangular openings 27a and 27b are formed (see FIG. 3) respectively. In the center side of the back cover 23, a retaining portion 28 projected behind the display device 1 is attached. The retaining portion 28 has four openings so as to face the back cover 23. To each of these openings, a hooking portion of supporting device, which is attached to the wall of the building, or a hooking portion of pillar is inserted. In each of four corners of the back cover 23, a grip 29 for carrying the display device 1 is provided.

To the back cover 23, an air intake unit 30 for entering the open air inside the cabinet 20, and the air exhaust unit 50 for exhausting the air inside the cabinet 20 to the outside of the display device 1 are attached. The air intake unit 30 has fans 31a, 31b and 31c for drawing air to the inside of the cabinet 20, an air intake side filter assembly 32 which excludes a dust included in the air inhaled by air intake fans 31, and a frame 33 to which the fans 31 and the assembly 32 is attached (see FIG. 3). Here, an axial flow type fan is employed as the air intake fans 31. The fans 31 are arranged inside the frame 33 and aligned along the long hand direction of the frame 33 (in other words, the short hand directions of the back cover 23). The frame 33 has a closed peripheral wall in four sides. In this wall, a sword guard 34 having a screwing hole is formed annularly. By inserting the edge of the frame 33 to the left hand side opening 27a of the back cover 23, and by screwing the sword guard 34 to the back cover 23, the air intake unit 30 is fixed to the back cover 23.

The air intake side filter assembly 32 has two rectangular shaped dustproof filters 35a, 35b and supporting member 36 for attaching these filters 35. The supporting member 36 is an elongated rectangular board. The two filters 35 are fixed along the long hand side of the supporting member 36.

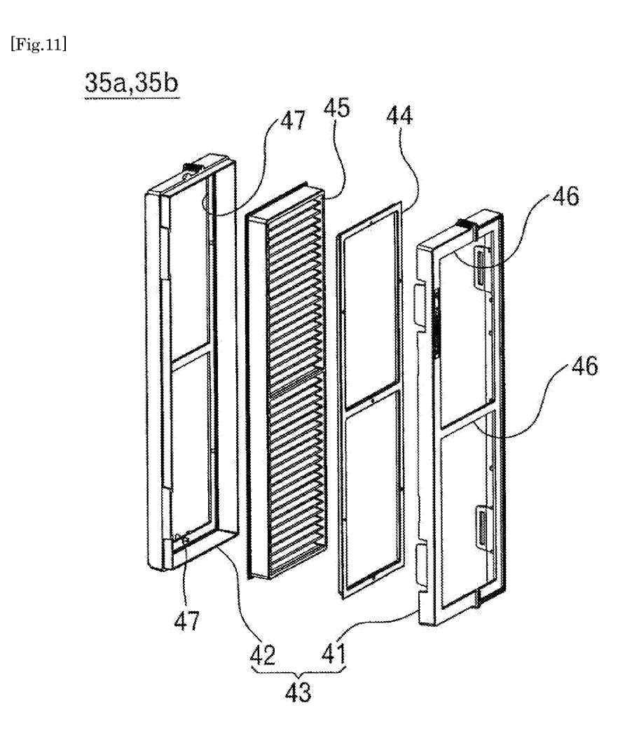

FIG. 11 is an exploded perspective view of the air intake side dustproof filter 35. Each of the filters 35 has an accommodation case 43 constituted by half case components 41 and 42. In the case 43, a mesh 44 and a filter material 45 having a dust collecting function are accommodated such that they are piled up. The mesh 44 is arranged at the outdoor side, and the filter material 45 is arranged at the cabinet 20 side. The case component 41 arranged in the mesh 44 side has two rectangle openings 46 formed inside. The opening 46 is for passing the air which is transmitted to the mesh 44 and the filter material 45. The case component 42 arranged in the material 45 side has two rectangle openings 47 formed inside. The opening 47 is for passing the air, which the dust is eliminated by the mesh 44 and the material 45.

In the external surface of the wall of the frame 33 of the air intake unit 30, a dent 37 is formed. In the bottom surface of the dent 37, slots 38a and 38b for filters 35a and 35b are provided (see FIG. 3). From lateral side of the frame 33, the filter 35 is inserted to the slot 38 and thereby the filter 35 is arranged inside the frame 33. By screwing the supporting member 36 to the frame 33 in a state the member 36 is inserted in the dent 37, the filter assembly 32 is fixed to the frame 33. In the instant application, the number of the dustproof filters 35 or the filter assembly 32 are not limited to the above example.

The structure of the air exhaust unit 50 is similar to the air intake unit 30. The air outlet 40 has three fans 51a, 51b and 51c, an air exhaust side filter assembly 52 arranged at the air discharge side of the fans 51, and a frame 53 for attaching the fans 51 and the assembly 52. The three fans 51 are arranged along the long hand side of the frame 53 (in other words, along the short hand sides of the back cover 23). Here, an axial fan is employed as the fans 51. The frame 53 has four sided closed peripheral wall. In the wall, a sword guard 54 having screw holes is provided. By inserting the edge portion of the frame 53 to the right hand side opening 27b of the back cover 23, and screwing the guard 54 to the back cover 23, the air exhaust unit 50 is fixed to the back cover 23.

The air exhaust side filter assembly 52 has a similar structure as the air intake side filter assembly 32. The filter assembly 52 has two rectangular shaped dustproof filters 55a, 55b and supporting member 56 for attaching these filters 55. The two filters 55 are fixed along the long hand side of an elongated rectangular board-like supporting member 56. In the external surface of the wall of the frame 53 of the air exhaust unit 50, a dent 57 is formed, and in the bottom surface of the dent 57, two slots are provided (see FIG. 3). The filter assembly 52 is fixed to the frame 53 in a similar manner with the filter assembly 32. In the instant application, the number of the dustproof filters 55 or the filter assembly 52 are not limited to the above example.

When the air intake fans 31a, 31b and 31c, and the air exhaust fans 51 are not driving, the air may intrude inside the cabinet 20 via air exhaust unit 50 from the outside of the display device 1. Considering this, the air exhaust side dustproof filter 55 is provided so as to exclude the dust intruding into the cabinet 20. Since the air exhaust side dustproof filter 55 does not need to have high dustproof performance compared with the air intake side dustproof filter 35, the filter 55 has a mesh but does not have a filter material.

As shown in FIGS. 3 and 4, in the both ends of the short hand side of the first frame 21, an air intake side guide component 13 and an air exhaust side guide component 16 are sandwiching the LCD panel 10. The air flow inside the cabinet 20 between the air intake unit 30 and the air exhaust unit 50 is specified by the guide components 13, 16 and the LCD panel 10. The rear side surface of the guide components 13, 16 contacts the edge of the air intake unit 30 and air exhaust unit 50 which are inserted respectively to the rectangle openings 27a, 27b of the back cover 23. On the surface of the air intake side guide component 13, three vents 14a, 14b and 14c each of which conforms to air intake fans 31a, 31b and 31c are provided. On the surface of the air exhaust side guide component 16, three vents 17a, 17b and 17c each of which conforms to air exhaust fans 51a, 51b and 51c are provided. The detail of the air flow inside the cabinet 20 is described later.

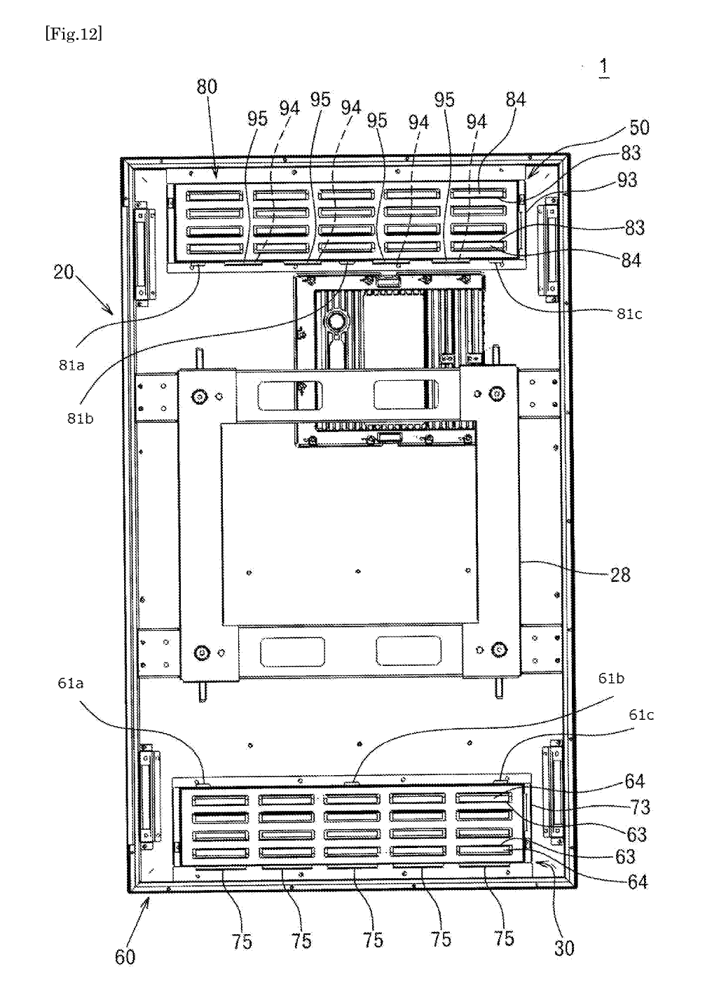

To the frame 33 of the air intake unit 30, an air intake side lid unit 60 covering the rear opening 39 of the unit 30 is attached. This lid unit 60 is attached to the frame 33 by hinges 61a, 61b, and 61c (see FIG. 2), and this enables the lid unit 60 to be in both opened state and closed state. To the frame 53 of the air exhaust unit 50, air exhaust side lid unit 80 covering the rear opening 59 of the air exhaust unit 50 are attached by hinges 81a, 81b, and 81c (see FIG. 12), and this enables the lid unit 80 to be in both opened state and closed state.

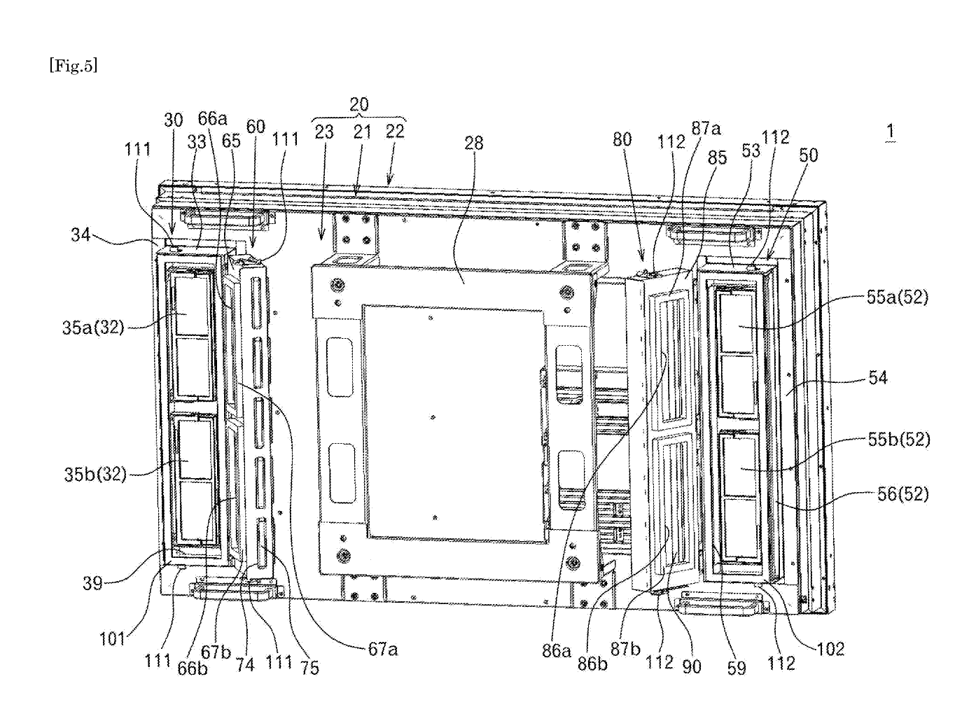

FIG. 5 is a rear perspective view of the display device 1, and shows the state where these lids 60 and 80 are opened. The Since the air intake side lid unit 60 and the air exhaust side lid unit 80 can rotate toward the center side of the display device 1 when opening these lids, a serviceman can easily inspect or clean the filters 35 and 55 by opening these lids from the closed state. As mentioned above, the hooking portion 28 of the display device 1 can be attached to the wall or pillars by using a supporting member attached on the wall or pillars. Thus, the display device 1 is designed to secure an enough space between the display device 1 and the wall so that the serviceman can open the lids 60 or 80 even when the display device 1 is attached to the wall.

In the frame 33 of the air intake unit 30 and the air intake side lid unit 60, locking mechanism 111 which locks the lid unit 60 in the closed state are provided. The lock mechanism 111 is constituted by, for example, a ring-shaped fastener formed in the lid unit 60 and a ligula formed in the frame 33 for fastening the fastener. As shown in FIG. 2, a lock mechanism 111a is formed on upper side of the frame 33 and the lid unit 60. A lock mechanism 111b is formed on lower side of the frame 33 and the lid unit 60. Similarly, a lock mechanisms 112a and 112b are provided on the frame 53 of the air exhaust unit 50 and the air exhaust side lid unit 80.

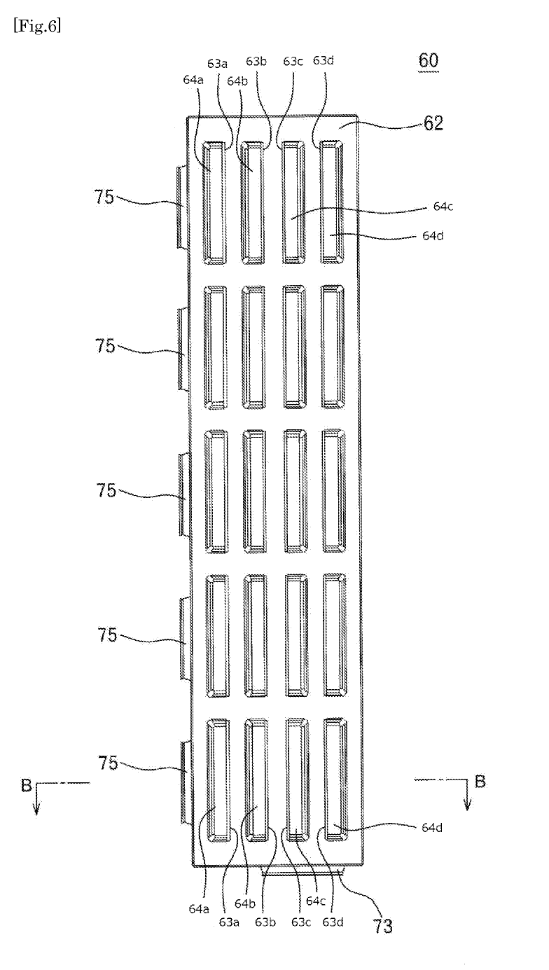

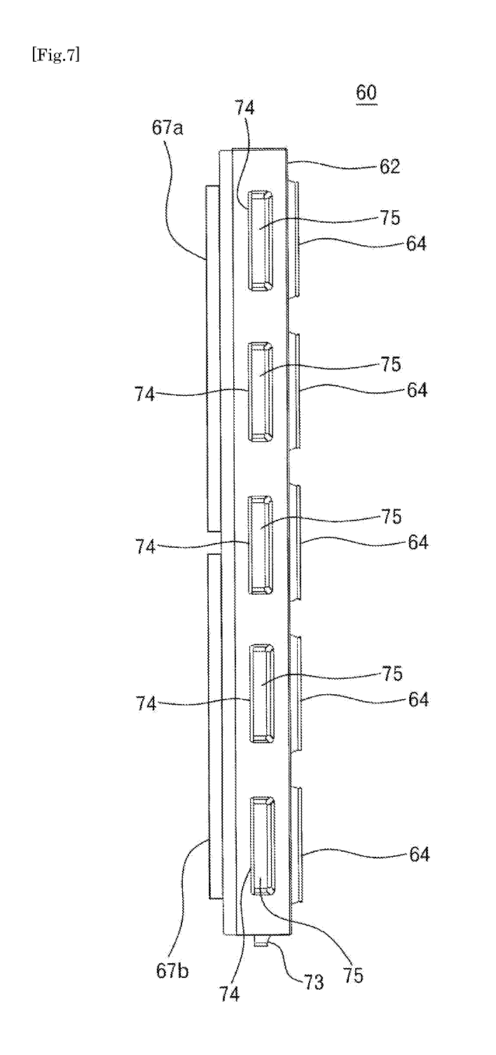

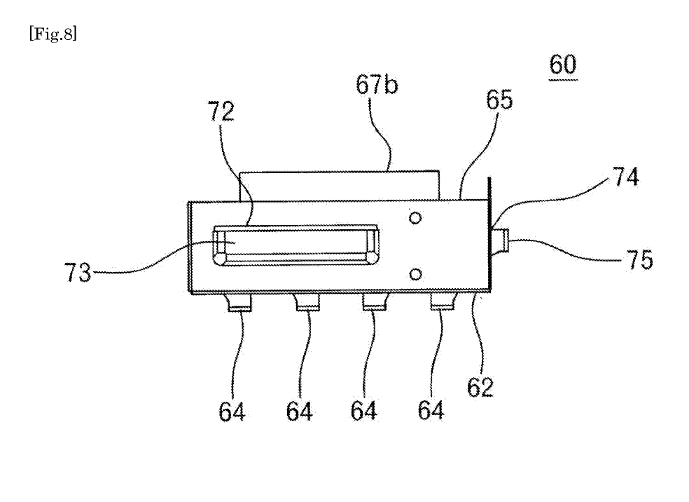

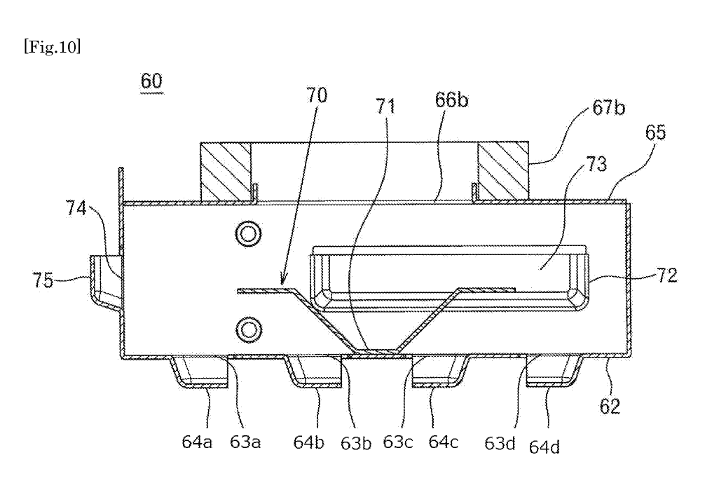

FIGS. 6, 7, 8 and 9 is a front view, a side view, a bottom view, and a rear view of the air intake side lid unit 60 respectively. FIG. 10 is a sectional view fractured at the plane containing a B-B line shown in FIG. 6. The lid unit 60 is rectangular and hollow shaped. In front side surface 62 of the lid unit 60, a plurality of vents 63 (air inlets 63) are formed. The dust or water outside the display device 1 cannot enter the air intake unit 30 and inside the cabinet 20 unless they do not enter inside the inner space of the lid unit 60. By this lid unit 60, intrusion of water or dust into the cabinet 20 from the air intake unit 30 is prevented. In an instant example, twenty air inlets 63 arranged at four rows and five lines are formed in the lid unit 60. In each of the inlets 63, a hood 64 which prevents water or dust from entering the lid unit 60 is provided. The hood 64 is formed so as to project outside on the surface 62 and covers the air inlet 63. The open end side of the hood 64 is perpendicular to the surface 62.

Referring to FIG. 6, hoods 64b of five inlets 63b in the second row from the left are opened toward right hand side (toward the inlets 63c neighboring the inlets 63b). Thereby, it can prevent water or dust coming from the left-hand side of the inlets 63b from entering inside the lid unit 60.

Hoods 64c of five inlets 63c are opened toward the left-hand side (toward the inlets 63b). Thereby, it can prevent water or dust coming from right-hand side of the inlets 63c from entering inside the lid unit 60.

Five inlets 63a in the first row from the left are provided in the left side of the inlets 63b, and hood 64a of the air inlet 63a is opened toward the right-hand side. Thereby, it can prevent water or dust coming from left-hand side of the inlets 63a from entering inside the lid unit 60.

Five inlets 63d in the first row from the right are provided in the right hand side of the air inlet 63c, and a hood 64d of the air inlet 63d is opened toward the left-hand side. Thereby, it can prevent water or dust coming from right-hand side of the inlets 63d from entering inside the lid unit 60.

On the other hand, water (raindrop) coming from the right hand side of the inlets 63a and 63b, or water (raindrop) coming from left hand side of the inlets 63c and 63d enter inside the air intake side lid unit 60 via inlets 63. However, the lid unit 60 has a structure so that the water entered inside the lid unit 60 does not reach the air intake unit 30.

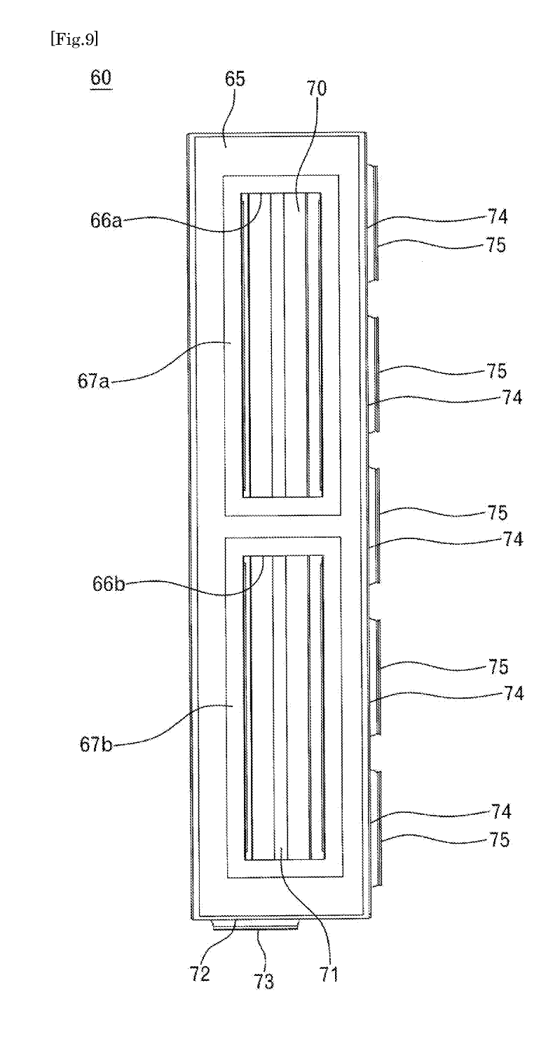

As shown in FIG. 9, in the rear side surface 65 of the lid unit 60, two openings 66a and 66b, each of which conforms to the filters 35a and 35b are formed in line along the long hand side of the surface 65. The air which flows inside from the air inlet 63 is transmitted to the air intake unit 30 via these openings 66. In the surface 65, first sealing components 67a and 67b surrounding each of the openings 66 are fixed to the openings 66. The first sealing components 67a and 67b are arranged along the edge of the openings 66a and 66b respectively, and are attached to the surface 65 by adhesives for example. A gasket made of rubber may be used for the first sealing component 67.

Each of the first seal components 67 conforms to each of the air intake side dustproof filter 35. When the air intake side lid unit 60 is in a closed state, the upper side first seal component 67a is contacted with the edge portion of the accommodating case 43 for the upper side filter 35a, and the lower side first seal component 67b is welded to the edge portion of the case 43 for the lower side filter 35b. Thereby, space between the lid unit 60 and the case 43 can be sealed and the air introduced from the air inlet 63 of the lid unit 60 is transmitted smoothly to the filter 35 via the opening 66. The number of the filters 67 or openings 66 may vary according to the number of the filter 35.

As shown in FIGS. 4 and 5, on the backside end of the frame 33 of the air intake unit 30, a second seal component 101 having four sides covering the opening 39 of the frame 33 is fixed. A gasket made of rubber is used for the seal component 101, and the gasket is adhered to the end of the frame 33. When the air intake side lid unit 60 is closed, the seal component 101 is connected to the back side surface 65 of the lid unit 60 by crimping so that it covers two of the first seal components 67. Thereby, the air intake unit 30 and the lid unit 60 are sealed watertight, and it can prevent water from invading inside the space between the frame 33 of the air intake unit 30 and the air intake side lid unit 60. Instead of the above example, the second seal component 101 may be formed in the air intake side lid unit 60.

As described above, in the front side of the air intake side lid unit 60, hood 64 for reducing the water invasion into the lid unit 60 is formed in the air inlet 63, however, when the display device 1 is exposed to a rainstorm, water may enters inside the lid unit 60 from the air inlet 63. Thereby, a intercepting board 70 is provided in the inner side of the front surface 62 of the lid unit 60, so that the water entered from the air inlet 63 is prevented from going toward the opening 66 in the rear surface 65 of the lid unit 60. As shown in FIG. 9, the intercepting board 70 is arranged along the long side direction of the lid unit 60 such that the air inlet 63 cannot be seen from the opening 66 when viewed the opening 66 from the surface 65 side of the lid unit 60.

As shown in FIG. 10, in the instant example, a belt-like board, which is bent such that a trapezoid convex 71 is formed along the long side direction, is used as the intercepting board 70. The apex plane of the convex 71 is connected to a plane between the air inlet 63b and the air inlet 63c. The water which entered from these inlets 63 fall to the bottom surface of the lid unit 60 by gravity after hitting the intercepting board 70, or after hitting the intercepting board 70 and the inner wall of the lid unit 60. The water which entered from the air inlet 63a and the air inlet 63d fall to the bottom surface of the lid unit 60 by gravity after hitting the inner wall of the lid unit 60.

Referring to FIG. 9, for example, in the bottom portion of the air intake side lid unit 60, a long holed opening (a first drain outlet 72) is provided along the short direction of the lid. The water which falls to the bottom surface of the lid unit 60 is emitted outside from the drain outlet 72 which is arranged downwards. The hood 73 is formed so as to cover the outlet 72, and is opened toward the air intake unit 30 or the back cover 23. The first drain outlet 72 also functions as an air inlet. The open end side of the hood 73 is formed perpendicular to the bottom surface of the lid unit 60. Instead of the intercepting board 70, a belt-like plate may be arranged parallel to the rear surface 65, supported by a certain component.

Referring to FIG. 2, a hinge 61 is attached to the center side lateral surface of the air intake side lid unit 60. In the opposite side of this lateral surface, which is a surface near the short direction edge of the cabinet 20, five openings (second drain outlets 74), in other words, five long holes are formed. The second drain outlets 74 are arranged along the long side direction of this lateral surface and in each of these drain outlets 74, hood 75 is formed so as to cover the drain outlets 74. Each of the hoods 75 is formed so as to cover the drain outlet 74 and is opened towards the air intake unit 30 or the back cover 23. The open end side of the hood 75 is formed perpendicular to the lateral surface of the lid unit 60. The second drain outlet 74 may also functions as an air inlet. The function of the inlet 74 is described in detail later.

As shown in FIG. 2, for example, the air exhaust side lid unit 80 has the similar structure as the air intake side lid unit 60. The air exhaust side lid unit 80 has a rectangular box-like shape having a hollow inside, as well as the air intake side lid unit 60. As well as the lid unit 60, the lid has a structure so that the dust or water outside the display device 1 does not invade inside the cabinet. In the front side surface 82 of the lid unit 80, twenty ventilation holes (outlets 83) are formed in four rows and five lines. In each of the outlets 83, a hood 84 is formed so as to protrude backward from the surface 82 and cover the air outlet 83. The open end side of the hood 84 is formed perpendicular to the surface 82. As well as the air intake side lid unit 60, in the air exhaust side lid unit 80, the hoods 84 of the outlets 83 in the two left rows are opened toward right-hand side, and the hoods 84 of the outlets 83 in the two right rows are opened toward left-hand side. By forming the outlets 83 and the hoods 84 as such, invasion of water or dust can be prevented in the lid unit 80.

As shown in FIG. 5, in the rear side surface 85 of the lid unit 80, two rectangular openings 86a and 86b are formed in the long side direction of the surface 85. When the lid unit 80 is closed, the air from the air exhaust unit 50 is sent to the air outlet 83 via the opening 86. In the surface 85, a third sealing component 87a and 87b are fixed surrounding each of the openings 86a and 86b. The seal component 87 is arranged along the edge of the opening 86, and is adhered to the surface 85. As for the component 87, a gasket made of rubber is used, for example.

Each of the third seal components 87 conforms to each of the air exhaust side dustproof filter 55. When the lid unit 80 is in a closed state, the upper side seal component 87a is attached on the edge portion of the accommodating case of the upper side filter 55a, and the lower side seal component 87b is attached on the accommodating case of the lower side filter 55b. Thereby, the lid unit 80 and the accommodating case of the filter 55 are sealed airtight, and thus the air passing the filters 55 is sent smoothly to the air outlet 83 via opening 86 of the lid unit 80. The sealing component 87 may be provided on the rear surface 85 of the lid unit 80. The number of openings 86 and the seal components 87 may vary according to the number of the filters 55.

In the backside end of the frame 53 of the air exhaust unit 50, a fourth seal component 102 surrounding the backside opening of the frame 53 is fixed. For the component 102, a gasket made of rubber is used, for example, and is adhered to the end portion of the frame 53. When the lid unit 80 is in the closed state, the component 102 is connected crimping to the rear side surface 85 so as to surround the third seal components 87a and 87b. Thereby, the air exhaust unit 50 and the lid unit 80 are sealed watertight, and it can prevent water from invading inside the cabinet thorough the clearance between the frame 53 and lid unit 80. Instead of the above example, the seal component 102 may be formed in the lid unit 80.

In the inner side of the front surface 82 of the lid unit 80, a intercepting board 90 is attached, and this prevents water from going toward the opening 86 of the rear side surface 85 of the lid unit 80. The intercepting board 90 is arranged in the long side direction of the lid unit 80 so that the air outlet 83 cannot be seen from the opening 86 from the rear surface 85 side.

As shown in FIG. 4, a intercepting board 90, which is similar to that of the air intake side lid unit 60, is used in the air exhaust side lid unit 80. The apex of the blade 90 is connected to the surface between the air outlets 83 in the second row and the third row from the left side. The water which entered from the air outlet 83 falls to the bottom part of the lid unit 80 as well as in the lid unit 60. The water which fell to the bottom of the lid unit 80 is discharged outside from a third drain outlet 92 arranged downward. In the drain outlet 92, a hood 93 is provided so as to project from the bottom side toward the lower side of the lid unit 80. The hood 93 is formed so that it covers the drain outlet 92 and is opened toward the air exhaust unit 50 or the back cover 23. The open end side of the hood 93 is formed perpendicular to the bottom surface of the lid unit 80. The third drain outlet 92 also functions as an air outlet.

In the center side lateral surface of the air exhaust side lid unit 80, hinges 81 are attached, and four long-holed openings (fourth drain outlets 94) are formed. Each the fourth drain outlets 94 are formed aligned in the long side of this lateral surface. In each of these outlets 94, a hood 95 protruding from this lateral surface toward the side direction is provided. Each of the hoods 95 is formed so as to cover the outlets 94 and is opened towards the air exhaust unit 50 or the back cover 23. The open end side of the hood 95 is formed perpendicular to the lateral surface of the lid unit 80. The fourth drain outlet 94 may also functions as an air outlet.

The display device 1 of an instant example can be utilized not only in a horizontal installation in which the long-side of the display device 1 is set to the horizontal direction as shown in FIG. 2, but also in a vertical installation in which the long-side of the display device 1 is set to the vertical direction as shown in FIG. 12. In the vertical installation, it is arranged so that the air intake side comes to the lower side and the air exhaust side comes to the upper side. As a result, a cool air enters from the lower side and a warm air which is heated by the LCD panel 10 is exhausted outside from the upper side, and thus the ventilation inside the display device 1 is achieved efficiently. Referring also to FIG. 10, in the vertical installation mode, water entering the air intake side lid unit 60 falls to its bottom surface, in which the second drain outlet 74 is arranged, and the water is emitted outside from this outlet 74. Further, in the vertical installation mode, the water entering the air exhaust side lid unit 80 falls to its bottom surface, in which the fourth drain outlet 94 is arranged, and the water is emitted outside from this outlet 94.

During the horizontal installation, the second drain outlet 74 is formed leftward. In other words, the outlet 74 is formed on the left hand lateral side of the air intake side lid unit 60. The fourth drain outlet 94 is also formed leftward, that is, on the left hand lateral side of the air exhaust side lid unit 80. Thereby, when the display device 1 is in the vertical installation mode, the air intake unit 30 is in the lower side and the air exhaust unit 50 is in the upper side, the thus water is exhausted from the second drain outlet 74 and the fourth drain outlet 94. If the display device is configured such that the air exhaust portion comes to the right side (when horizontal installation mode) and the air intake portion comes to the left side, these drain outlets should be arranged on the right hand side.

The hood 73 of the first drain outlet 72 and the hood 75 of the second drain outlet 74 are opened toward the air intake unit 30 and the back cover 23. Thus, it can prevent the water from invading inside from the second outlet 74 during the horizontal installation, and from the first outlet 72 during the vertical installation. Thereby, the intrusion of the water inside the air intake side lid unit 60 is prevented. Further, the hood 93 of the third drain outlet 92 and the hood 95 of the fourth drain outlet 94 are opened toward the air exhaust unit 50. Thus, it can prevent the water from invading inside from the fourth outlet 94 during the horizontal installation, and from the third outlet 92 during the vertical installation. Thereby the intrusion of the water inside the air exhaust side lid unit 80 is prevented.

An arrow in FIG. 4 shows the air flow inside the display device 1 when the air intake fans 31 in the air intake unit 30 and the air exhaust fans 51 in the air exhaust unit 50 are driving. The air which flowed inside from the air inlet 63, the first drain outlet 72, and the second drain outlet 74 of the air intake side lid unit 60 passes inside the lid unit 60, and is sent to the air intake side dustproof filter 35 via the opening 66. The air which the dust is removed by the filter 35 is drawn by the fan 31, and is transmitted to the space inside the air intake side guide component 13. The front glass 26 of the front cover 22 is arranged away from the display panel 10. The air transmitted inside the guide component 13 is guided by the component 13 and the rear or lateral surface of the display panel 10, and is transmitted to the space between the front glass 26 and the display panel 10. The air which is transmitted to this space moves from one end to the other end of the display panel 10 absorbing the heat generated from the panel 10 and then reaches the air exhaust side guide component 16. The air entering the guide component 16 is drawn by the air exhausting fan 51. The air exhausted from the fan 51 is sent inside the air exhaust side lid unit 80 via the air exhaust side dustproof filter 55 and the opening 86 of the lid unit 80. The air transmitted to the lid unit 80 is emitted outside of the display device 1 from the air outlet 83, the third drain outlet 92 and the fourth drain outlet 94 of the lid unit 80.

In a side wall of the air intake side guide component 13 which is perpendicular to the rear surface of the LCD panel 10, a plurality of holes 15 are formed along the short hand direction of the display screen. In the side wall of the air exhaust side guide component 15 which is perpendicular to the rear surface of the LCD panel 10, a plurality of holes 18 are formed along the short hand direction of the display screen. Thus, a part of air sent to the space in the air intake side guide component 13 passes through the holes 15, and flows along the rear side of the LCD panel 10 to reach the air exhaust side guide component 16, by absorbing heat from the rear side of the panel 10. Then the air is sent inside the guide component 16 from the holes 18, and then exhausted outside the display 1 device.

As described above, in the display device 1, the cabinet 20 is configured by combining the first frame 21, the front cover 22, and the back cover 23. To the second frame 24 of the front cover 22, a front glass 26 is attached. To the back cover 23, the air intake unit 30 and the air exhaust unit 50 are attached. Further, the air intake side filter assembly 32 is attached to the air intake unit 30, and the air exhaust side filter assembly 52 is attached to the air exhaust part 50. These components in the display device 1 are configured so that the neither the water nor dust reaches the LCD panel 10.

The inventor has built the prototype of the above mentioned display device 1 and achieved a field test. As a result, the performance of IP53 was satisfied not only in the horizontal installation but also in the vertical installation. The number the following the letter “IP” regards to dustproof performance. When this number is “5”, it is secured that the dust which deteriorates the safety or operation of the display device 1 does not enter inside the cabinet 20. The second digit after the letter “IP” regards to waterproof performance. When this number is “3”, it is secured that the display device 1 is not harmed by water entered from an angle less than 60 degrees.”

The number or geometry of the air inlet 63, the air outlet 83, the first drain outlet 72, the second drain outlet 74, the third drain outlet 92, and the fourth drain outlet 94 is not limited to the above example.

When the display device 1 is not installed vertically, the second drain outlet 74 and the fourth drain outlet 94 are not necessary to be formed.

### (Structure of the Front Cover 22)

According to the display device disclosed in the above-mentioned publication JP2011-128432A1, dust may attach to the display surface of the LCD panel due to ventilation by fan. Thus, it is necessary to clean the display surface periodically. Conventionally, the front glass is fixed to an escutcheon (front cover) and this escutcheon is screwed to the cabinet. Thus, at the time of the cleaning, it is necessary to remove the screw, however, in order to prevent escutcheon from falling apart, it is necessary to lay down the display device so that the displaying surface face upward and this makes cleaning troublesome. In detail, first it is necessary to carry the display device to a table so that the display device can be laid down. Further, the outdoor use display device equipping a waterproof or dustproof structure usually has large weight. Thus, it is necessary to hire a plurality of workers in order to carry the display device.

Thus, the first cover 22 of the display device 1 is fixed to first frame 21 and the front cover 22 can be opened or closed centering the upper side of the frame 21. This structure is explained in detail with reference to FIGS. 13 to 18.

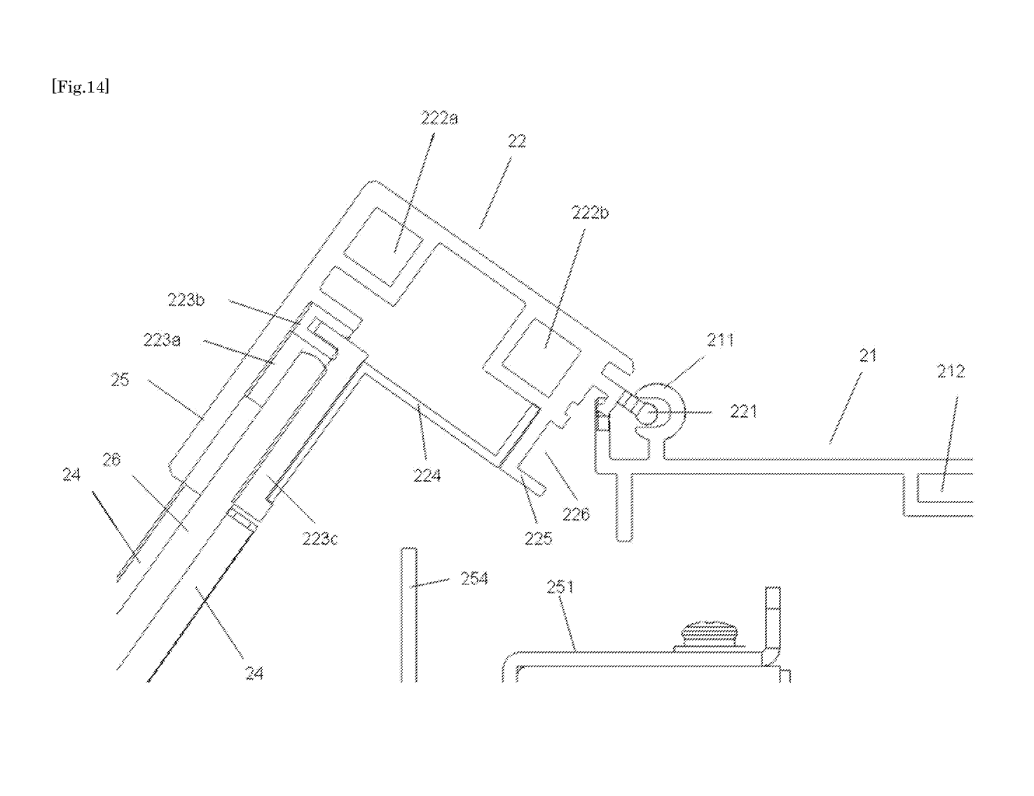

FIG. 13 is a side view of the display device 1, when assuming that the display device 1 is fractured at the plane containing the B-B line in FIG. 2, and the front cover 22 is opened. FIG. 14 is an enlarged view of the jointing section of the front cover 22 and the first frame 21 in FIG. 13. As shown in these figures, in the front cover 22, the front glass 26 is accommodated. In the first frame 21, LCD panel 10 is accommodated. In the front edge side of the upper surface of the first frame 21, a semicircular groove-like structured receptacle portion 211 is provided. On the other hand, in the rear edge side of the upper surface of the front cover 22, a spherical projection portion 221 is formed. The projection portion 221 can fit to the receptacle portion 211, and centering this receptacle portion 211, the front cover 22 can rotate. Thereby, the front cover 22 can be opened and closed, and by opening the front cover 22, the front side of the LCD panel 10 can be cleaned.

Referring to FIG. 14, the fixed structure of the front glass 26 will be described. The front glass 26 is fixed to the front cover 22 by sandwiching the flange 25 of the front cover 22 in the front side and the glass holder 224 in the rear side of the glass 26 intervened by gaskets 223a, 223b and 223c. In FIG. 14, it looks as if the second frame 24 is sandwiching the front glass 26. However, the second frame 24 shown in this figure is actually located on the lateral side of the display device 1, and thus the second frame 24 is not sandwiching the front glass 26 in the central portion of the display screen, Squared hollowed portion 222a and 222b are provided for fitting the L-shaped metal fitting. This metal fitting is used for connecting the portions of the second frame 24 which is actually divided into four frame portions, that is the upper side frame, the right side frame, the lower side frame, and the left side frame.

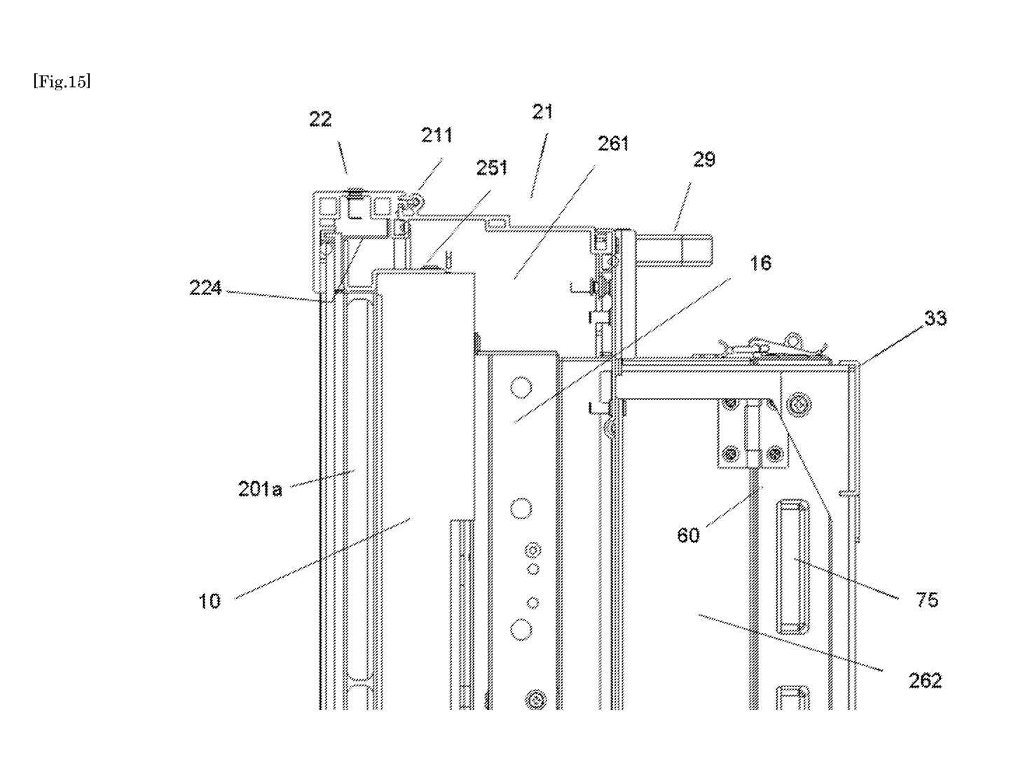

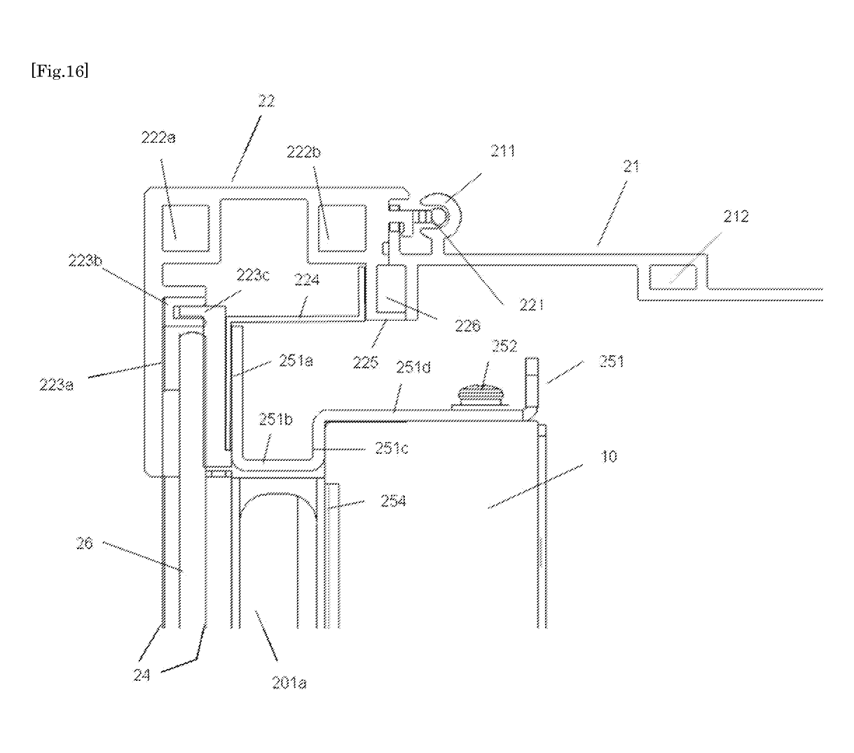

FIG. 15 is a side view of the display device 1, when assuming that the display device 1 is fractured at the plane containing the B-B line in FIG. 2, and the front cover 22 is closed. FIG. 16 is an enlarged view of the jointing section of the front cover 22 and the first frame 21 in FIG. 15. When the front cover 22 is closed, the glass holder 224 contacts the first plane 251a which is a front side surface of the metal component 251 provided on the upper side of the LCD panel 10. Thereby, a semi-sealed space 202 is formed between the front glass 26 and the LCD panel 10 (also see FIG. 4). Into this space, the air ventilated by air intake fans 31a, 31b and 31c flows in, and thereby the front side of the LCD panel 10 is cooled. The second surface 251b of the metal component 251 forms the upper surface of the space 202. The third surface 251c of the metal component 251 contacts the front surface of the LCD panel 10 and supports the front side of the LCD panel 10. The fourth surface 251d of the metal component 251 contacts the upper surface of the LCD panel 10. In the fourth surface 251d, a penetration hole for penetrating the screw 252 is provided, and by using screw 251, the metal component 251 is fixed to the upper surface of the LCD panel 10.

In the rear upper side of the front cover 22, a protrusion 225 is provided and to the upper space 226 of this protrusion 225, a gasket is fitted. This space 226 is actually formed so as to surround the LCD panel 10, and the gasket is arranged so as to enclose the LCD panel 10. Thereby, an invasion of the water to the LCD panel 10 is prevented.

The first frame 21 is divided into four portions as well as the second frame portion 24. Each of the frame portions is located in the upper side, right side, lower side and the left side of the LCD panel 10 respectively. Each of the divided frames 21 is connected by L-shaped metal fitting. The hollowed portion 212 is for inserting these metal fittings.

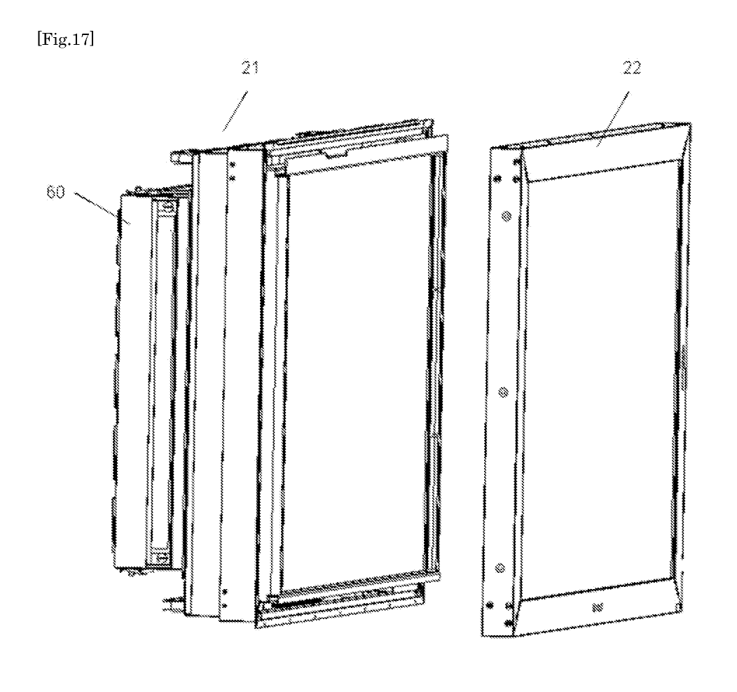

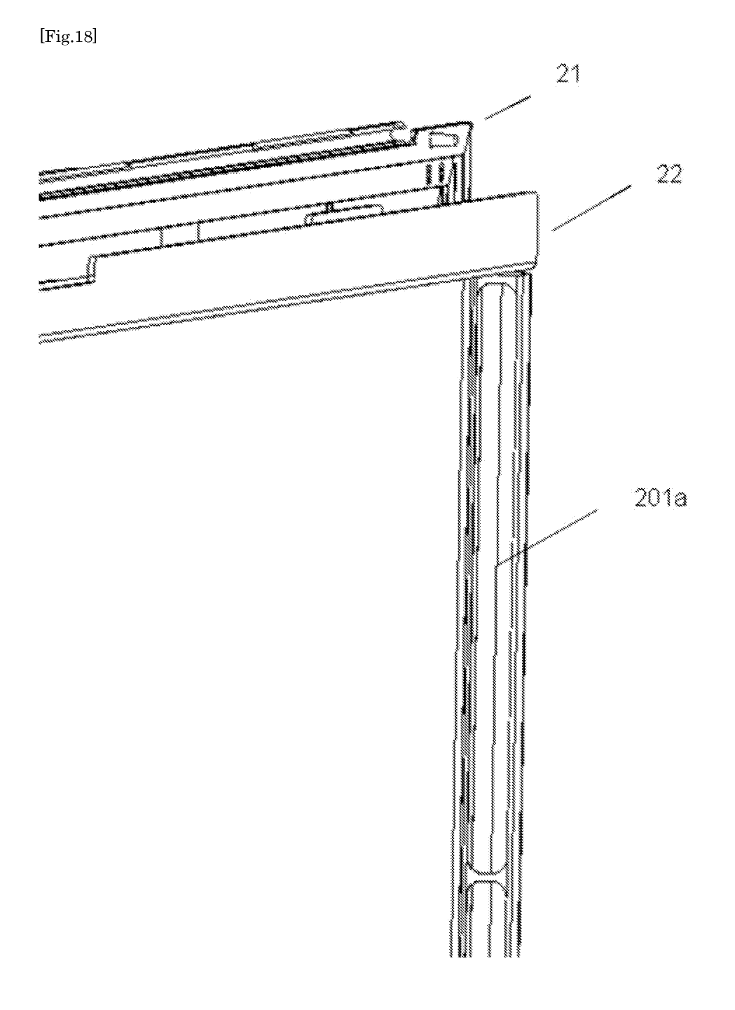

FIG. 17 is an exploded perspective view of the display device 1 when viewed from the front side. FIG. 18 is an enlargement view of the FIG. 17, specifically the lateral side part of the frame front cover 22 is enlarged. The air flow generated by an air intake fan 31 flow into the space 202 via the opening 201a provided in the front lateral side of the LCD panel 10. A frame-like component which is above the space 202 in FIG. 16 is equivalent to this opening 201a.

In the above example, the air intake side lid unit 60 is formed in the air intake unit 30 and the air exhaust side lid unit 80 is formed in the air exhaust unit 50. However, depending on the installation situation of the display device 1, these lids 60 or 80 may be removed, for example, when the display device 1 is installed on a place under a roof. In the above example, a similar dustproof or waterproof structure is applied in both air intake side and the air exhaust side. This means that the main idea of the present invention can be applied to both air intake side and the air exhaust side of the display device 1.

The display device of the above example is installed in the outdoor for displaying an image or information. For example, the display device is installed in order to show an advertisement to a pedestrian. Such display device may be installed attached to an outer wall of the building or to a pillar built on the ground, or may be installed inside other apparatus such as vending machine.

It should be noted that the above example are described for explaining of the invention is not intended for limiting the scope of the claimed invention. It should be also noted that the above configuration may be modified variously with in the scope of the claimed invention.

1. A display device comprising:
a display panel;
a cabinet configured to accommodate the display panel;
a ventilating portion configured to communicate with the space inside the cabinet;
a lid configured to cover the ventilating portion;
a first and second vents formed on the lid;
a first hood provided on the first vent, the first hood has an opening facing the second vent, and
a second hood provided on the second vent, the second hood has an opening facing the first vent.

2. The device of claim 1, further comprising:
an intercepting board which prevents water entered from the first or second vent from advancing toward the ventilating portion.

3. The device of claim 2, further comprising:
a protection glass arranged in front of the display panel, and
a fan component provided inside the ventilating portion, the fan component is configured to make an air flow in a space between the display panel and the protection glass.

4. A display device comprising:
a display panel;
a cabinet configured to accommodate the display panel;
an air intake portion configured to intake air to the cabinet;
an air exhaust portion configured to exhaust air from the cabinet;
a first lid configured to covers the air intake portion;
a second lid configured to covers the air intake portion;
an air inlet provided on the rear side of the first lid;
a first drain outlet provided on the lateral side of the first lid;
an air outlet provided on the rear side of the second lid, and
an second drain outlet provided on the lateral side of the second lid, wherein
the first and the second drain outlet are arranged on the same side.

5. A display device comprising:
a display panel;
a transparent protection component arranged in front of the display panel;
a cabinet configured to accommodate the display panel;
an accommodating unit configured to accommodate the transparent protection component, and
a fan component configured to make air flow in a space between the display panel and the transparent protection component, wherein
the accommodating unit is fixed rotatable to the cabinet.
